(19) United States
(12) Patent Application Publication
(10) Pub. No.: US 2006/0203460 A1
(43) Pub. Date: Sep. 14, 2006

(54) Apparatus, method and system of thin client blade modularity

(76) Inventor: Soffer Aviv, Moshay Eln Ayals (IL)

Correspondence Address: Angenehm Law Firm, Ltd., P.O. Box 48755, Coon Rapids, MN, 55448-0755, US

(21) Appl. No.: 11/076,558

(22) Filed: Mar. 8, 2005

(51) Int. Cl. H05K 7/10

(52) U.S. Cl. 361/788; 361/733; 361/730; 361/796

(57) ABSTRACT

The present invention provides a modular chassis comprising of multiple thin-client blades removeably connectable to a common midplane and to one or more power supplies and one or more management modules to simulate multiple thin-client operating with one or more computer networks. The invention enables building large-scale computer laboratory environments having many thin-client devices and possibly many simulated users, easily connected and managed to simulate large computer infrastructure. Also disclosed in this patent is a method for performing combinations of functions including testing and simulation of normal and abnormal operational scenarios in complex server-based computing environments.

### FIELD OF THE INVENTION

The present invention relates generally to multiple thin-clients modular system, and in particular, but not exclusively, to a thin-client blade system and architecture to enable functional and load testing of complex server based computing environments.

### BACKGROUND OF THE INVENTION

In the first years of Personal Computing, each Personal Computer (PC) workstation was operated as a stand-alone system and therefore the testing of big PC deployment was typically limited to testing a single PC for functionality, stability and reliability. As organizations' computer systems became networked and heavily relying on centralized servers, PCs became dependent on network and server resources for their normal operation. The typical computer system of a large organization became much more complex and therefore much more difficult to predict, simulate, and test.

Today, large organization are faced with the challenge of designing, analyzing, and maintaining not only the individual PC workstations, but the system as whole, including the complex interaction of multiple workstations requesting data or computing resources and loading the communication networks. Specifically, it become crucial to ensure that failure or overloading at any segment would not deteriorate into a catastrophic system failure.

Until now, the common practice among large organization was simulating the organization systems by building a small-scale model of the organization's computer system from the actual components (PC's servers, etc.) and operating each PC workstation with actual user performing tasks normally performed in the organization. This approach could only simulate small portion of the organization's system while suffering from relatively high cost.

A typical large organization synthetic computer laboratory described above would include many PC workstations; each connected to monitors or Keyboard Video Mouse switch (KVM), network switches, multiple servers and storage devices etc. With this non-production environment, the organization was capable of testing different operational scenarios, testing new software and hardware deployments, and performing system scaling, training and auditing without interfering with the operational systems (production) in the organization.

The main disadvantages of such simulated environment are:

1 High capital investment cost in constructing the testing system due to expensive building blocks—actual PCs and the large floor space needed for the laboratory.

2 High maintenance cost due to the complex wiring needed for network and multiple channel KVMs. In addition, the distributed management of the environment requires extensive workforce to manage and troubleshoot.

3 Lack of scalability in the workstation side—it was not practical to deploy several hundreds of PC workstations as it requires very large space, peripherals, and cabling.

4 Long setup and lack of flexibility—each setup or change may take days or weeks to build and verify due to all the cabling involved.

Another popular option available today is to use many virtual machines running on smaller number of physical computers to reconstruct the organization. While this option may be much more cost efficient than the previous option, the level of fidelity achieved with such system for workstation simulation is far from the level needed for most organization. It is difficult to predict the behavior of large distributed systems without the use of the actual hardware such as workstations. Still, virtual machines can offer the best solution for other segments in the simulated system such as servers and storage.

Today, with the server consolidation and server based computing trends, more and more PC workstations are being operated as client only and many are replaced by thin-client. This brings an even stronger challenge for the large organizations to ensure reliable and economical system operation. With the thin-client trend, came also the inherent risk of centralized failures that can paralyze the organization's Information Technology (IT) system, partially or completely. Scenarios such as security attack, virus, data-center failure, network failures and sudden loads can easily replicate and cause domino effects and therefore are extremely difficult to predict, to avoid, and to recover from.

Thin-client technology, on the other hand brought a unique opportunity for the large organization enabling them to efficiently deploy and maintain large synthetic labs at small space and lower cost of ownership. In addition, the use of thin-client workstations can be an efficient tool to simulate PC workstations as well.

Although there is an option to use multiple virtual (simulated) clients running on a single platform as simulated user workstation in the case of a thin-client workstation, the simulation will be even less reliable than in PC workstations as thin-clients are using completely different architectures and are difficult to simulate in current virtual machines.

To overcome these risks and to define and approve safe architectures for large thin-clients deployments, there is a need to develop tools and methods that will enable a realistic large-scale user workstations simulation with the actual workstation hardware and software being used in the target production environment.

Therefore, there is a need for a compact, high-density, rapidly-deployable, highly managed multiple thin-client system having centralized management and serviceability, and unlimited scalability. The thin-client blade system would provide essential component of Information Technology laboratories and data center operators to test and train different operational scenarios.

General background relating to the field of thin-client modular array system can be found in the following publications:

1. “Modular server architecture with Ethernet routed across a backplane utilizing an integrated Ethernet switch module”—United States Patent Application 20020124114, Bottom, David A.; et al. Sep. 5, 2002

2. “Blade server module”, U.S. Pat. No. 6,665,179, Chou Dec. 16, 2003

3. “Server blade chassis midplane printed circuit board with cover”, United States Design Patent D493,152 Baker, et al. Jul. 20, 2004

4. “Server blade chassis with airflow bypass damper engaging upon blade removal”, U.S. Pat. No. 6,771,499, Crippen, et al. Aug. 3, 2004

5. “Apparatus and system for functional expansion of a blade”, U.S. Pat. No. 6,819,567, Baker, et al. Nov. 16, 2004

6. “Test system for testing components of an open architecture modular computing system”, United States Patent Application 20040230866, Yates, Kirk; et al. Nov. 18, 2004

7. “HP Consolidated Client Infrastructure (CCI)—Help reduce enterprise IT costs”, White paper from HP 5982-1133EN Rev. 2, 11/2003

### SUMMARY OF THE INVENTION

Accordingly, it is a principle object of the present invention to overcome the disadvantage of prior art and to provide modular thin-client devices, systems and methods for using modular thin-client modules.

In an embodiment of the invention, a modular chassis comprising of multiple thin-client blades removeably connectable to a common Midplane or backplane and to one or more power supplies and one or more management modules to enable multiple thin-clients operating with one or more computer networks. The invention enables building large-scale computer laboratory environments having many thin-client workstations and possibly many simulated users, easily connected and managed to simulate large computer infrastructure. Internal KVM functionality and Chaining options enables a single administrative user to easily monitor and manage large number of thin-client workstations remotely or locally through a single set of keyboard, mouse and display.

Also disclosed in the present invention is a general method for performing combinations of functions including testing and simulating normal and abnormal operational scenarios in complex server-based computing environments.

In another embodiment of the invention, a modular thin-client blade system is disclosed. The system comprises: a modular chassis with multiple bays capable of accepting thin-client blade module inserts; at least one Midplane or backplane having connectors for each bay, a common power bus and management bus interconnecting said blade bays; plurality of thin-client blades removeably connectable to the said Midplane or backplane through mating connectors compatible with the said Midplane or backplane connectors; at least one network interfaces connecting each of at least one thin-client blade to a network through a network switch or hub.

In some embodiments, the system according to further preferred embodiment comprises a management module to centrally monitor, configure and control each of said plurality of thin-client blade modules.

In some embodiments, the KVM module is capable of chaining with plurality of similar systems to enable centralized management of more thin-client blades than can be inserted into one of said chassis.

In some preferred embodiments of the present invention, a thin-client blade chassis configured for accepting plurality of insertable thin client blade modules is provided. Said chassis, comprising: a modular chassis with multiple bays capable of accepting thin-client blade module inserts; at least one Midplane or backplane having connectors for each bay, a common power bus and management bus interconnecting said blade bays; a KVM module capable of connecting a user keyboard, mouse and display to a selectable one of said thin-client blade modules; and at least one power supply module to provide power to said modular thin-client blades.

In some other preferred embodiments of the invention, an insertable thin-client blade module device is provided. Said client blade modules, comprising: a mating connector configured to interface with Midplane or backplane connector for receiving power from said Midplane or backplane connector and exchanging information with said midplane or backplane; a LAN transceiver connected to: said mating connector, a LAN connector and a LAN controller; a processor processing said information; a volatile memory for storing information and program instructions used by said processor; a non-volatile memory for storing program instructions used by said processor; and a bus connecting said: LAN controller, non-volatile memory, volatile memory and processor.

In some embodiments of the present invention, an insertable management module is provided. Said management module comprising: a mating connector configured to interface with Midplane or backplane connector for receiving power from said Midplane or backplane connector and exchanging information with said midplane or backplane; a mating connector configured to interface with midplane connector for receiving power from said backplane connector and exchanging information with said Midplane or backplane; a LAN transceiver connected to: said mating connector and a LAN controller; a processor processing said information; a volatile memory for storing information and program instructions used by said processor; a non-volatile memory for storing program instructions used by said processor; an I/O controller capable of exchanging information with user input/output device; a video controller capable of generation video signals; and, a bus connecting said: I/O controller, video controller, LAN controller, non-volatile memory, volatile memory and processor.

In yet other preferred embodiments of the invention, a method for constructing large scale, centrally manageable multi thin-client system is provided. Said method comprises the step of: providing plurality of thin-client blade chassis each configured for accepting plurality of insertable thin client blade modules, each comprising: a modular chassis with multiple bays capable of accepting thin-client blade module inserts; at least one Midplane or backplane having connectors for each bay, a common power bus and management bus interconnecting said blade bays; a KVM module capable of connecting a user keyboard, mouse and display to a selectable one of said thin-client blade modules; chaining said KVM modules of at least two of said plurality of thin-client blade chassis.

In additional preferred embodiments of the present invention, a method for simulating a multi thin-client system is provided. Said method comprising the step of: providing plurality of thin-client blade chassis each configured for accepting plurality of insertable thin client blade; inserting plurality of thin-client blades and a single management module in each of said plurality of thin-client blade chassis; connecting each of said plurality of thin-client blades to a network switch; connecting said network switch to a server.

Further features and advantages of the invention will be apparent from the drawings and the description contained herein.

### BRIEF DESCRIPTION OF THE DRAWINGS

An exemplary embodiment of the invention is described in the following section with respect to the drawings. The same reference numbers are used to designate the same or related features on different drawings. The drawings are generally not drawn to scale.

For a better understanding of the invention reference may be made to the preferred embodiments of the invention shown in the accompanying drawings where:

FIG. 1 illustrates a frontal view of a modular thin-client blade system with multiple thin-client blade modules and a single management module assembled in accordance with a preferred embodiment of the present invention.

FIG. 2a illustrates a frontal view of a thin-client blade module in accordance with a preferred embodiment of the present invention.

FIG. 2b illustrates a front panel of thin-client blade module with Digital Video Interface (DVI) and Universal Serial Bus (USB) ports according to another embodiment of the present invention.

FIG. 3 shows a frontal view of a Management module in accordance with a preferred embodiment of the present invention.

FIG. 4 illustrates a block diagram of a thin-client blade system in accordance with a preferred embodiment of the present invention.

FIG. 5 illustrates thin-client blade module interfaces schematics to Midplane internal bus in accordance with a preferred embodiment of the present invention.

FIG. 6 presents a thin-client blade system interconnection with the network switch and a server in accordance with a preferred embodiment of the present invention.

FIG. 7 illustrates a preferred embodiment of thin-client blade system.

FIG. 8 depicts a block diagram of a single thin-client blade module in accordance with a preferred embodiment of the present invention.

FIG. 9 depicts a block diagram of a Management module in accordance with a preferred embodiment of the present invention.

FIG. 10 depicts more detailed description of the KVM module and its external connections according to an embodiment of the present invention.

### DETAILED DESCRIPTION OF EXEMPLARY EMBODIMENT

The following detailed description is of the best presently contemplated modes of carrying out the present invention. This description is not to be taken in a limiting sense, but is made merely for the purpose of illustrating the general principles in accordance with the present invention. The scope of the present invention is best defined by the appended claims.

The foregoing and other objects, features and advantages of the invention will become apparent from the following more particular description of exemplary embodiments of the invention, as illustrated in the accompanying drawings:

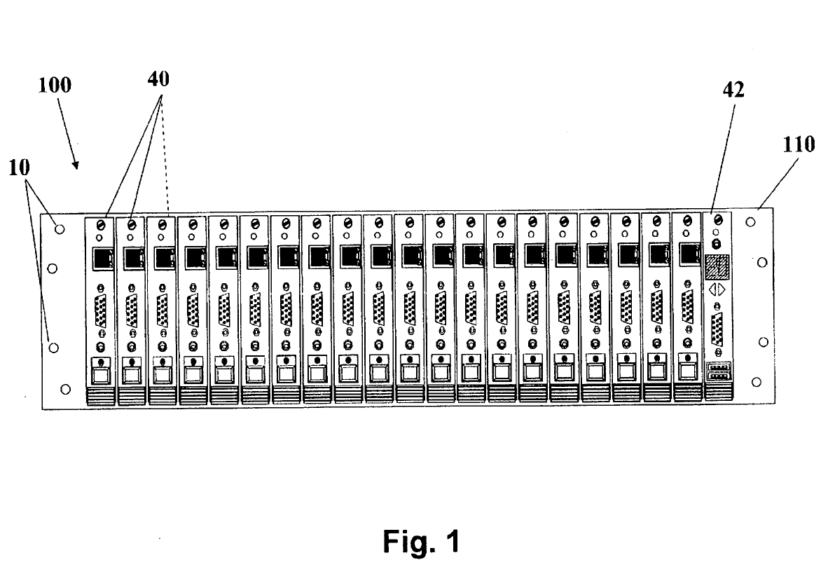

Reference is made to FIG. 1 illustrating a frontal view of an embodiment of a thin-client modular blade system 100. Chassis rack mounting holes 10 are used for securing a chassis 110 to a standard rack. Typically, standard 19″ rack geometry is being used to enable vertical buildup of multiple sets of thin-client modular blade systems 100 and network switches as needed. Chassis 110 is fitted with multiple thin-client blades modules 40 and a single management module 42. Thin-client blade modules 40 are substantially identical but in general, the user can install up to 20 modules of the same type or with mixture of types. The user can also partially fill chassis 110, depending on modules availability and the target system defined by the user. Management module 42 enables centralized management and monitoring of all modules. Chassis 110 structure enables plurality of thin-client blade modules 40 to be installed in it. Thin-client blade modules 40 may be available in plurality of types. Plurality of modular blade types may flexibly be installed in the same or separate chassis to create plurality of system characteristics as needed.

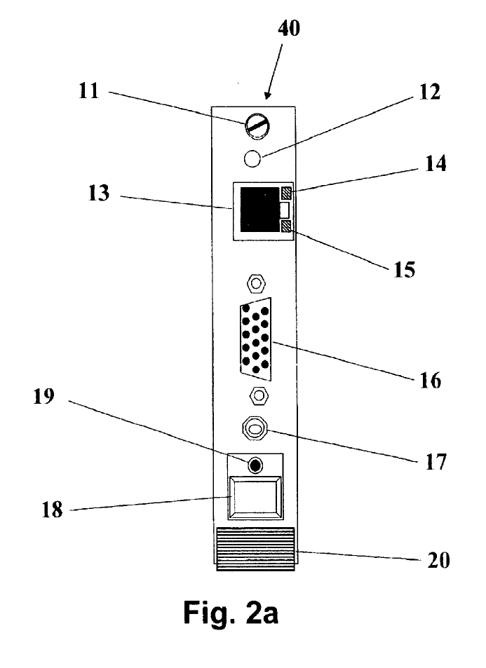

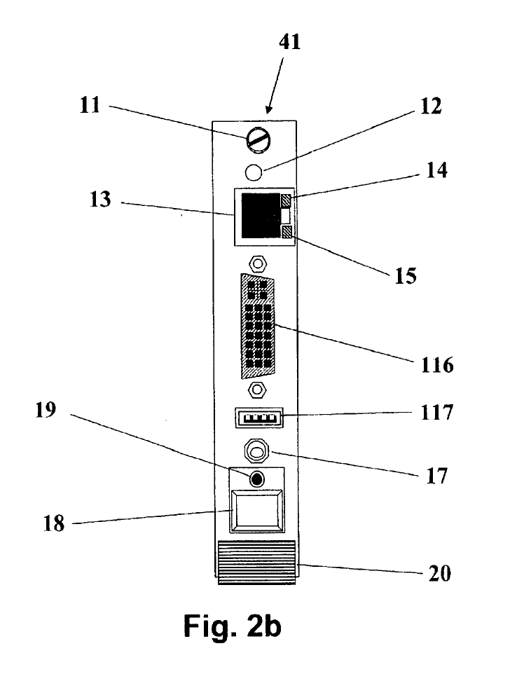

Reference is now made to FIG. 2a which is a more detailed frontal view of an exemplary thin-client blade module 40 according to a preferred embodiment of the present invention. Thin-client Blade Module 40 is optionally secured to chassis 110 by fastener 11. Fastener 11 may be a captive screw, Dzus fastener or a screw.

Optionally, thin-client blade module 40 is equipped with indicator 12. Indicator 12 may be in a form of a Light Emitting Diode (LED) or combination of LED's capable of generating colored light indicating the current status of the Thin-client Blade Module. For example, green light may be used to indicate module normal operation status while red light may indicate module failure.

LAN jack 13 is used for connecting the module to an external Network switch is preferably a shielded RJ-45 jack. External cabling is preferably used to attach thin-client blade module 40 to the network switch or hub to enable maximum flexibility in network selection and configuration.

Optional two LEDs 14 and 15 integrated into the LAN jack indicate LAN Link and Activity status, respectively. These lights provide the user with quick and visible network status information for system installation, monitoring and maintenance.

Optional analog video out jack 16 enables a direct connection of a computer display to thin client blade module 40.

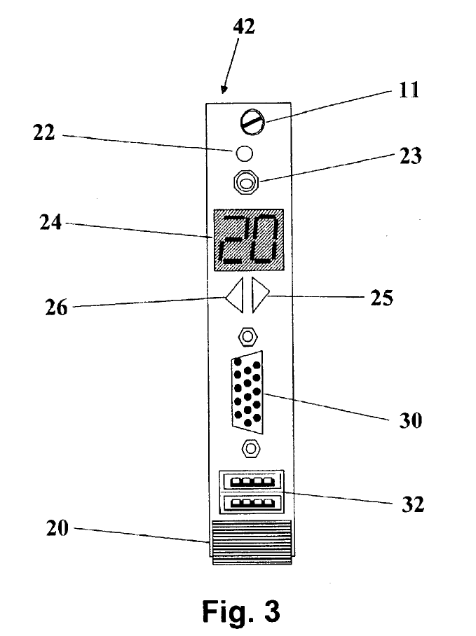

Optional Power—Reset switch 17 is preferably a 3 position momentary switch with dual action—pushing it upwardly will power on or off the module alternatively; pushing it downwardly will reset the module causing the thin-client to reboot. Preferably, reset and power on may be centrally controlled through management module 42 to be described in more details in FIG. 3.

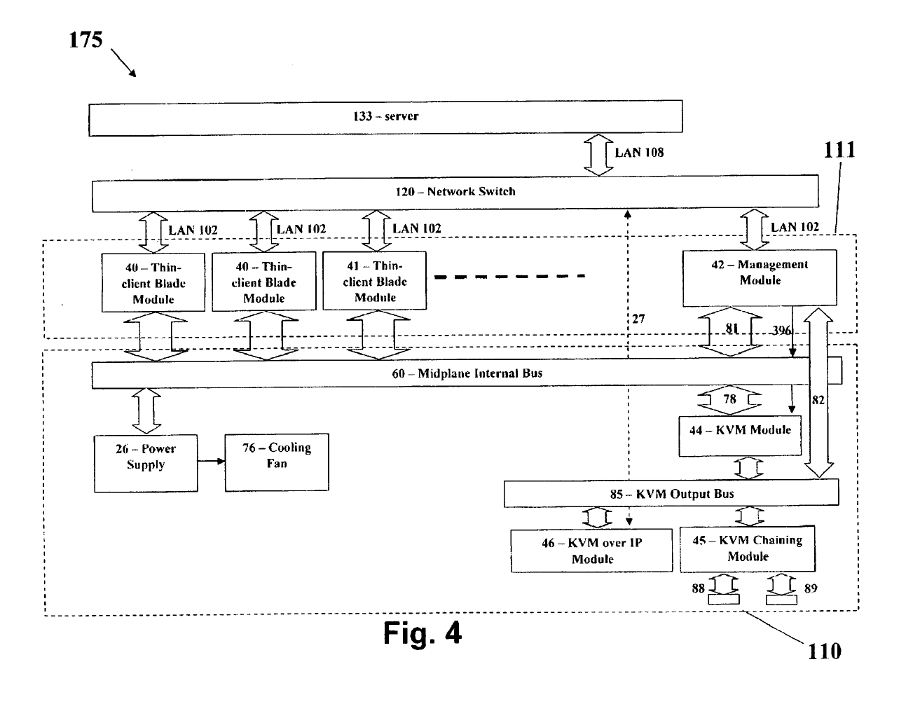

Optional KVM Module selected indicator 19, preferably in the form of a LED indicates which of the plurality of thin-client blade modules is currently selected by an internal KVM module 44 located in chassis 110 (module 44 is shown in FIG. 4). Preferably, Green LED 19 will illuminate indicating which one of the plurality of thin-client blades modules was remotely selected by management module 42.

Optional push button 18 is a KVM manual override switch. When KVM manual override switch 18 is pressed, KVM module 44 within the chassis is instructed to select the specific thin-client blade module on which the KVM manual override switch was pressed. This manual selection may override other selections previously made by the user through the management module controls. In this case, KVM selected indicator 19 will be illuminated in green.

Optional ejector 20 serves as module lock and ejection aid. Ejector 20 may be fitted with a switch to notify management module of imminent module removal/installation. This may be needed to enable hot-swap functionality where modules are replaced while the system is powered on.

Alternatively, thin client blade module 40 is a headless thin-client blade having at least a LAN connector 13 on its front panel while missing some or all the other abovementioned elements.

Alternatively, or additionally, module 40 comprises additional elements on its front panel. For example one or few of: keyboard connector, mouse connector, Universal Serial Bus (USB) connector, audio connectors, additional indicators etc.

Reference is now made to FIG. 2b illustrating a front view 41 of t-client blade module with Digital Video Interface (DVI) and Universal Serial Bus (USB) port according to another preferred embodiment of the present invention.

Thin client blade module 41 is optionally secured to chassis 110 by fastener 11. Fastener may be a captive screw, Dzus fastener or a screw.

Optionally, thin client blade module 41 is equipped with indicator 12. Optional indicator 12 may be in a form of a Light Emitting Diode (LED) or combination of LED's capable of generating light indicating the status of the modular blade. For example, green light indicates module normal operation status while red light indicates module failure.

LAN jack 13 is used for connecting the module to an external Network switch which is preferably a shielded RJ-45 jack.

Optional two LEDs 14 and 15 integrated into the LAN jack indicate LAN Link and Activity, respectively.

Optional digital video (DVI) out jack 116 enables a direct connection of digital computer display to the module. Utilizing DVI out jack 116 allows more flexibility than the use of analog video out jack. For example, a display monitor may be placed at larger distance from the blade module. DVI may be implemented with digital signals only or with a combination of digital and analog outputs to support older analog displays as well.

Optional USB port connector 117 enables direct connection of external USB peripherals such as keyboard and mouse to thin client blade module 41.

Optional Power—Reset switch 17 is preferably a 3 position momentary switch with dual action—pushing it upwardly will power on or off the module; pushing it downwardly will reset the module. Preferably, reset and power on may be centrally controlled through management module 42 to be described in FIG. 3.

Optional KVM selected indicator 19, preferably in the form of a LED, indicates which of the plurality of blade is selected by internal KVM module 44 located in chassis 110 (shown in FIG. 4). Preferably, Green LED in indicator 19 will illuminate indicating which one of the plurality of thin-client blade modules was remotely selected by management module 42.

Optional push button 18 is KVM manual override switch. When KVM manual override switch 18 is pressed, KVM module 44 within chassis 110 is instructed to select the Thin-client Blade Module on which the KVM manual override switch was pressed. In this case the KVM selected indicator 19 will be illuminated green.

Optional ejector 20 serves as module lock and ejection aid. Ejector 20 may be fitted with a switch to notify management module of module removal/installation. This may be needed to enable hot-swap functionality where modules are replaced while the system is powered on.

Reference is now made to FIG. 3 illustrating in a detailed view the management module 42 front panel. In this front view of an exemplary embodiment of the present invention, optional fastener 11 and optional ejector 20 are the same as in the previous figures.

Optional Main power indicator 22, preferably LED, is power indicator for the whole system. For example, when illuminated green, power is available to the chassis and all modules.

Main power switch 23, preferably a secured toggle switch, used for powering on and off alternatively the system's chassis and all modules. This switch may be connected to the power supply to provide power up and power down logic commands.

Optional display 24 provides a readable alphanumeric display showing system status codes and optionally selected module number. Preferably, display 24 is a small Liquid Crystal Display (LCD) or segmented LED display.

Optional forward key 25 and backward key 24 are used to enable the user to manually select specific thin-client blade module at the chassis or even in different chassis with chaining option.

Analog Video out connector 30 is output for display connected internally to a KVM module 44 (shown in FIG. 4). By selecting the proper module, the user may monitor each one of the operating modules 40 or 41 through a single video out port 30. USB ports 32 are preferably two USB ports to connect the user's mouse and keyboard. These ports are internally connected to the KVM module 44 to enable interaction with each one of thin-client blade modules 40.

Reference is now made to FIG. 4 depicting a block diagram of an embodiment of the invention showing the connections between various components assembled in modular system 175. The main components of system 175 are chassis 110 with its insert compartment 111 holding plurality of thin client blade modules 40, a single management module 42, network switch 120, and server 133.

Multiple thin-client modules 40 or 41 are connected to midplane internal bus 60 at the back of insert compartment 111 through matting connectors. Thin-client blade modules 40 or 41 receive power supplied by a power supply 26 through Midplane Internal Bus 60. Thin-client blade modules 40 receive (and optionally transmit) certain control commands from and to Midplane Internal bus 60. Bus 60 receives from modules 40 or 41 video signals. Midplane bus 60 receives from and transmits to thin-client blade modules 40 or 41 various I/O control signals such as USB, serial, system management bus, and audio. Midplane internal bus 60 is also connected to a single management module 42.

As mentioned herein before, a KVM module 44 is preferably located in chassis 110. Alternatively, KVM module 44 may be located externally or even remotely of the chassis. KVM module 44 is connected to Midplane internal bus 60 through link 78 that enables it to receive and transmit various Thin-client module signals. These signals may include USB, Video, audio and various control signals to be selected by the KVM module 44. The selected thin-client module signals are connected to KVM Output Bus 85.

KVM Module 44 serves as a logical selector switch between multiple input/output signals linked to thin-client modules 40 and one set of the same signals to enable connection of a single user display, keyboard and mouse. KVM output bus 85 delivers the selected module signals to management module 42 via Midplane Internal Bus 60 and also to an optional KVM over IP Module 46 and KVM Chaining Module 45. The KVM output signals passed through the management module 42 connected to the video connector 30 and USB connectors 32 at the front panel of management module 42 (shown in FIG. 3).

Optionally, management module 42 uses a unique connector and serves as a termination for all bus signals. In this embodiment management module 42 may be inserted in a designated location in chassis 110. It is also connected to KVM chaining module 45 to enable cascading several modular blade rack systems 175. Chaining between multiple chassis enables the user to control and monitor large number of Thin-client blade modules without the need to physically connect or disconnect its display, keyboard and mouse. Chaining can be achieved by special cables connected at the back of each system chassis specifically for this purpose. These cables are capable of delivering analog and digital signals between two chassis. With multiple cables like that chaining multiple chassis one can construct a chained structure of multiple chassis managed through a single management module. Another alternative for managing multiple systems through one console is through the LAN when KVM over IP option installed or through special chaining in connector 88 and Chaining Out 89 connector located at the chassis backside. These chaining connectors are used to cascade multiple number of the chassis to form a large structure managed by a single management module that becomes the master module.

Optional KVM over IP Module 46 provides remote access and control to the system through a standard web-browser. This module contains a computer that runs a dedicated web-server service to deliver video, audio, mouse, and keyboard interaction through standard web pages. A LAN interface 27 of KVM over IP module 46 connects the module to the Network switch and to the proper network. This enables other computers or thin-clients in the network to connect to that system and manage its functions.

Single or multiple power supplies 26 provides low voltage DC power through Midplane Internal Bus 60 to power the various system modules. Power supplies 26 is typically connected to the mains power input or to −48 DC supply. Field Effect Transistors power switching may be used to support modules hot swapping and remote power management through power switching.

Optionally, a cooling module 76 may be added to provide a forced flow of cooling air through the system. In most cases, this module would not be implemented as the thin-clients and especially Reduced Instruction Set Computing (RISC) based devices are relatively low power devices.

Preferably external or internal Network switch 120 connect each one of the system thin-client blade modules 40 or 41 to the network/s using LAN lines 102 connected to LAN connector 13 in each one of the Thin-client Blade modules (LAN connectors 13 is shown in FIGS. 2a and 2b).

Alternatively, switch 120 may be integrated within the chassis. Optionally, Midplane internal bus 60 may include LAN connectors eliminating the need for lines 102 and connectors 13.

Switch 120 may be unmanaged or preferably managed switch to enable specific programming and settings for each port and attached module independently Another advantage of the managed switches is its capability to define Virtual Local Area Networks for each port. An internal or external programmable bandwidth limiting feature may be added to enable various Local Area Networks (LAN) and Wide Area Network (WAN) simulation.

Switch 120 is preferably a rack-mounted Network switch, preferably mounted above or below chassis 110 so as to shorten the length of cables 102.

Server 133 is connected to switch 120 by LAN cable 108. Server 133 may be a rack-mounted server or a standard server located in proximity or remotely from the rack.

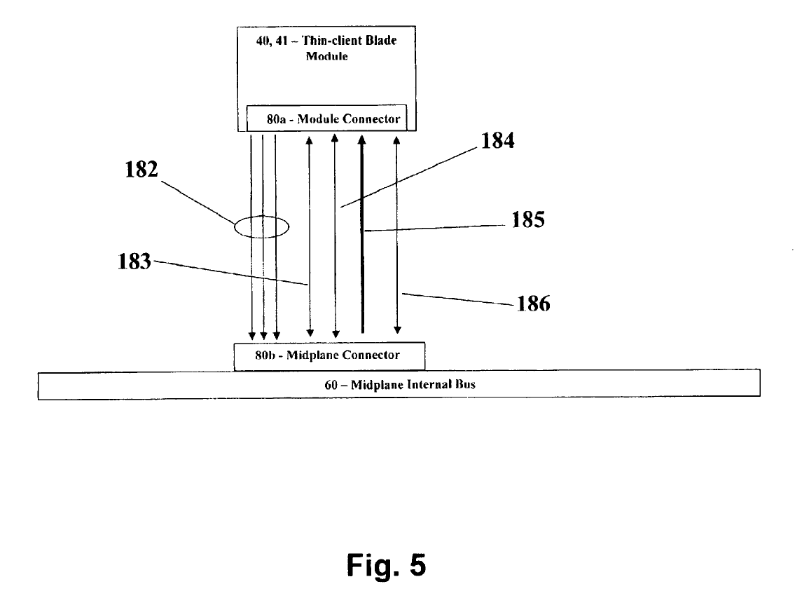

Reference is now made to FIG. 5 depicting more detailed view of the various interconnections between thin-client blade modules 40 or 41 and system Midplane Internal Bus 60. These interconnections typically pass through module connector 80a on the Thin-client blade module which mattes with Midplane connectors 80b on Midplane Internal Bus 60.

Digital or analog video output 182 pass from thin-client blade modules 40 or 41 to Midplane Internal Bus 60. It is then switched by the internal KVM module 44 to enable a single display device to selectively connect to any selectable blade module.

Line 183 is USB port line connecting thin-client blade modules 40 or 41 to Midplane Internal Bus 60. From Midplane Internal Bus USB is routed to the KVM module where it is switched into a single USB port connected to the user's mouse and keyboard through front panel connectors fitted in a management module panel 42 or through other (chained) systems that eventually terminated with a USB connector.

Control signals 184 interconnecting various management function in the management module with each thin-client blade modules 40. These signals are used to detect the module modes and settings, to deliver power and status information, and to enable various switching functions such as module select, reset and power switching.

Power supply to the thin-client blade module is passed through power plane 185. This is typically a high-current trace routed through heavy-duty connector contacts to reduce voltage drops and power noise. Certain power pins in connectors 80a and 80b may be shorter to assure that power to the module will be connected last and disconnected first when installing and removing a module under chassis power.

Audio in and Out signals 186 are passed to Midplane Internal Bus 60 and from there it is routed to internal KVM module 44.

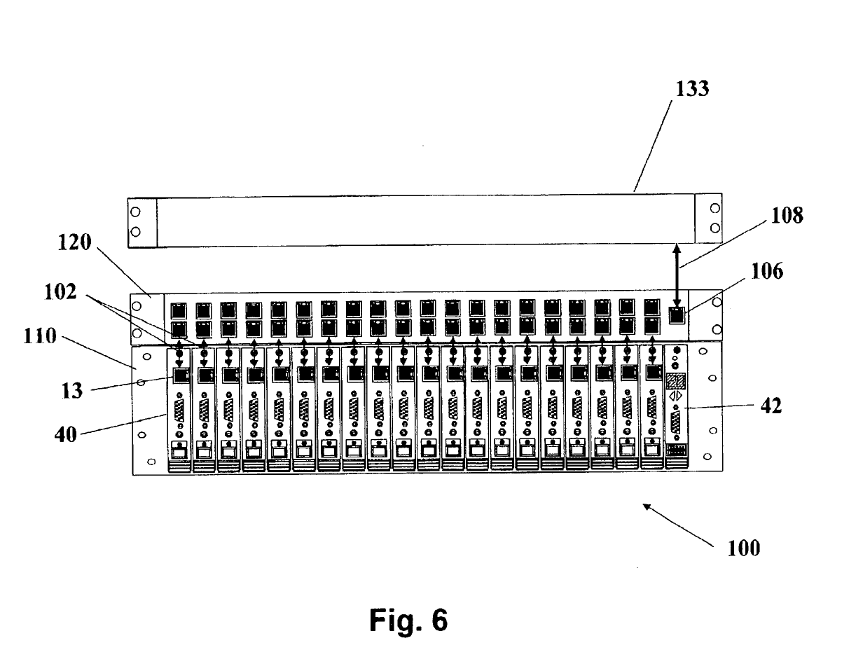

Reference is now made to FIG. 6 that is a high-level system diagram showing the thin-client modular blade system interconnections in accordance with a preferred embodiment to the present invention. One or more thin-client blade modular systems 100 connected to one or more Network switches 120 through short LAN cables 102 that bridge between each module LAN port 13 and its respective port in the Network switch.

Management module 42 may also be connected to the Network switch to enable remote management over IP and remote KVM functionality.

Uplink port 106 in Network switch 120 is connected with LAN cable or fiber connection 108 to server/s 133 to form a complete server-based-computing environment. Server/s 133 may be physical servers or multiple virtual servers as needed. This basic system may be easily expanded to scale to many more thin-client modular blade systems, additional LAN and WAN equipment and simulators and multiple servers and server blades and storage equipment.

Using the present invention, it is relatively simple to build and manage large number of thin-clients. A standard 42U rack for example may be fitted with 12×3U thin-client blade modular systems to form a 240 thin-clients system. With this arrangement, each thin-client modular blade chassis encloses up to 20 thin-client blade modules and two similar racks are sharing one 1U 48 ports managed Network switch. Higher density chassis can be constructed with the same methodology to enable more thin-client blades at even smaller space.

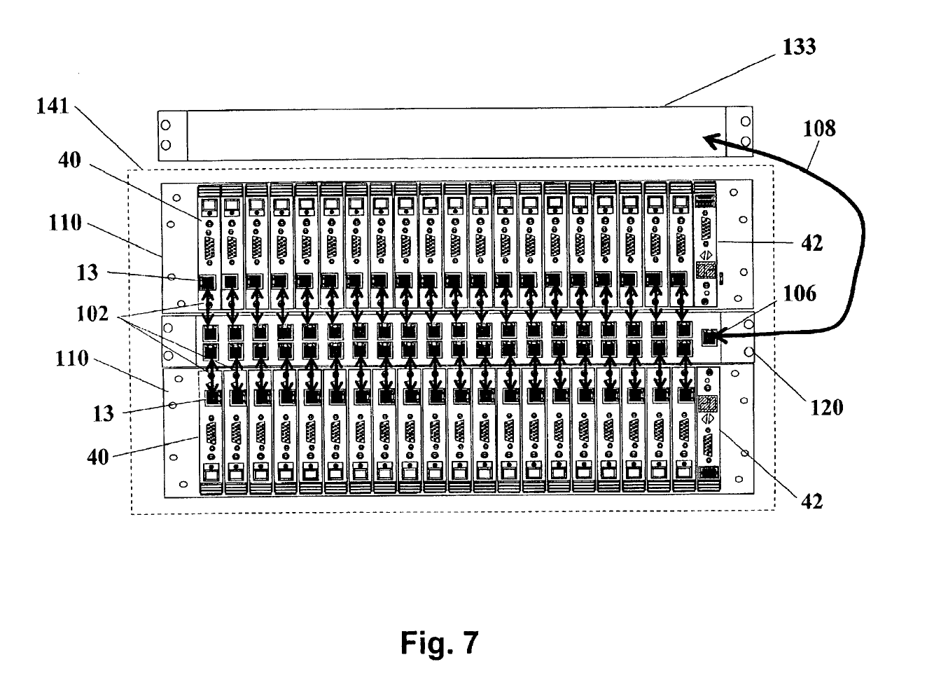

Reference is now made to FIG. 7 depicting high-level system diagram showing preferred embodiment thin-client blade modular system 141. One Network switch 120 is sandwiched between two chassis 110. When fully populated, each chassis 110 contains twenty thin-client blade modules 40 or 41 and one Management module 42. Short LAN cables 102 connect each LAN port 13 on thin-client blade modules 40 or 41 to the Network switch 120.

An uplink port 106 in Network switch 120 is connected with LAN cable or fiber connection 108 to server/s 133 to form a complete server-based-computing environment. Plurality of systems 141 may be constructed and be serviced by single or multiple servers 133.

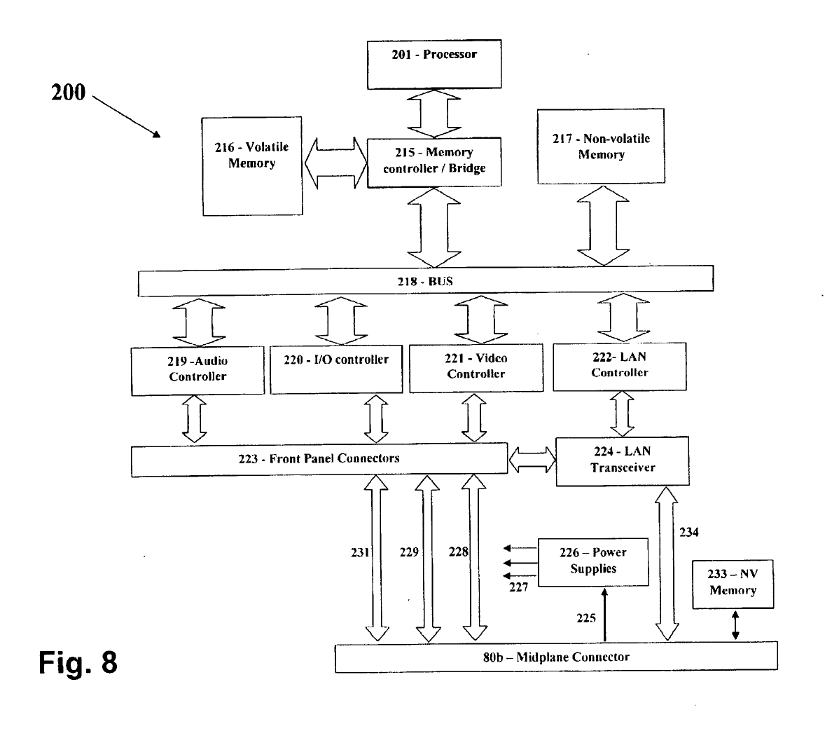

Reference is now made to FIG. 8 depicting a block diagram 200 of a Thin-client Blade module according to a preferred embodiment of the present invention. This drawing shows a block diagram of typical computing apparatus such as depicted in FIG. 2.

Thin-client blade system 200 is a data processing electronic system capable of performing Thin-client or simulated PC workstation functions comprising of one or more of each of the following components:

Processor 201 process stored programs and data entered by user or simulated user as needed, peripherals and network. Processor 201 is preferably chosen from available Reduced Instruction Set Computers (RISC) for their lower power consumption and low heat generation. Alternatively, a Complex Instruction Set Computer (CISC), Security and encryption engine, Digital Signal Processor (DSP) or any other type or combinations of digital processor with sufficient processing power may be used to implement a device structure that is similar to the real target Thin-client device that it is simulating. Processor 201 may include an on-die high-speed cache memory or an external cache or combination of the two.

A Memory controller/bridge 215 interface processor 201, with volatile memory 216 and Bus 218. This function and others may be integrated with processor 201 or installed separately in different chips or chip-sets. Volatile memory 216 is used for storage of temporary data as needed by processor 201. Memory 216 may be RAM type, SDRAM, DDRAM or any other type of volatile memory.

Internal bus 218 connects the various parts of the Thin-client blade module and may be a single or multiple buses, 16, 32 or 64 bit PCI or any other bus type. If multiple buses are implemented, then bus bridges modules may be added to interface and drive the different buses.

Non-volatile memory 217, connected to bus 218, permanently stores data, programs, and settings required for the Thin-client blade module operation.

Optional Audio controller 219 such as AC-97 CODEC is connected to bus 218 and to optional audio connectors on the front panel of thin client blade module 40. Audio controller 219 is used for conversion of analog audio signal into digital stream and vise versa. Digital streams to and from the audio controller may be available directly on internal bus 218 or on a dedicated CODEC bus such as AC Link. A dedicated bridge or glue-logic may be implemented to interface between bus 218 and the said Audio controller 219. In addition this module may contain various analog stages such as mixers, switches, attenuators, filters, amplifiers etc. Also, this module may include additional functionality and enhancements to support improved sound output for home theatre and multimedia applications. Audio circuitry may be single channel (Mono), dual channel (stereo), or more to enhance multimedia experience. Audio input and output may also connected through link 244 to Midplane connector 80a to enable audio selection function in the KVM module 44 shown in FIG. 4.

I/O controller 220 connected to bus 218 on one side and to I/O connectors on the front panel and appropriate I/O busses in the Midplane connector 80b through link 239 on the other side. Controller 220 is used for enabling direct connection of standard peripherals through standard ports such as USB, PS/2, Serial, Parallel, IEEE-1394 etc. on the module front panel 40 or to enable indirect switched peripherals connection through the KVM. This controller 220 may also provide switched power source to power external peripherals.

Video controller 221, connected to bus 218 from one side and to video connector on the front panel of thin client blade module 40 and is connected to Midplane connector 218 through link 228 on the other side. It is used for driving an external analog or digital monitor directly or through the KVM indirectly. Video controller 221 may contain internal video memory, external video memory or it may share the said volatile memory 216 with processor 201 in Unified Memory Architecture (UMA) structure.

Local Area Network controller or Media Access Controller (MAC) 222, connected to bus 218 is used for interfacing the Thin-client blade module with the Network switch or hub through a LAN transceiver (physical layer module) 224.

Connectors and ports located on the front panel of thin client blade module 40 are used for direct connection of various external peripherals to the module without the need to pass through the KVM module. This may be useful for troubleshooting or to allow a continuous monitoring of one or more blade modules of special interest to the user. These connectors connect the various ports such as the Audio controller 219, I/O Controller 220 and Video Controller 221. Front panel may also contain some switches and indicator lights to enable a direct control and monitoring of that blade module.

Local Area Network transceiver 224 (physical layer module) interface between LAN controller (MAC) 222 and the LAN jack located at the front panel of thin client blade module 40. It is also optionally connected to Midplane connector 80b through link 224 to enable internal Network switch implementation. Transceiver 224 may contain a discrete magnetics or magnetics integrated in the LAN jack. The availability of the LAN jacks on the blade module front panel 40 is especially useful to allow the user to easily connect and monitor that LAN connection of each blade module. In this design, thin-client blade modules on the same chassis may be connected to different Network switches, routers, hubs, or networks. LAN Transceiver 224 may be connected to the Local Area Network controller 222 by means of Media Independent Interface (MII) bus or by other interconnection buses. Local Area Network 224 transceiver may support 100BASE-TX, 100BASEFX, 10BASE-T and Giga LAN or other LAN protocols as required.

Power supplies 226 uses the power available on Midplane bus through the Midplane connector 80b and link 225 to convert that power into an appropriate voltage/s output 227 required by the different thin-client module circuits. Power supplies module 226 may also include timing circuitry to provide power up sequencing for other circuits. It also may contain reset signal/s generation to enable proper starting and power interruption detection.

Midplane connector 80b may also be connected to an optional Identification Non-volatile memory module 223. This memory module may be used to store the specific Thin-client module model, serial number, MAC address and various module settings and configuration. When module is being inserted or when power is available in the chassis, this information may be read by the management module to enable better modules management functions.

The preferred Thin-client blade module embodiment described herein may run local operating system such as Microsoft Windows CE, Linux or any other compatible embedded operating system. If the implemented hardware compatible with standard x86 or limited size x86 then it can also run more common x86 operating system such as, Microsoft® Windows XP or XP embedded. The operating system can run plurality of local programs to enable connection to remote servers. These programs may include Citrix ICA client to communicate with Citrix server, Microsoft Terminal Services RDP client to support remote Windows servers and various local terminal emulations to communicate directly with legacy systems. Running such clients enables the thin-client computing device to run applications in a session that runs in the remote server.

In addition to that the thin-client computing apparatus may run plurality of independent local applications such as web-browser, multimedia players and dedicated user applications.

Furthermore, the thin-client computing apparatus may also contain remote management agent/s. These agents enables the organization to manage device and user settings remotely. It may also enable centralized software deployment and user authentication and security monitoring.

Furthermore, a plurality of load simulation local and remote programs can be run at each thin-client blade module to enable realistic simulation of users with different load profiles.

Optionally, system 200 further comprises a memory device 233 installed in each thin-client blade module 40 and accessible to the management module through a bus to positively identify the type model and unique characteristics of that module.

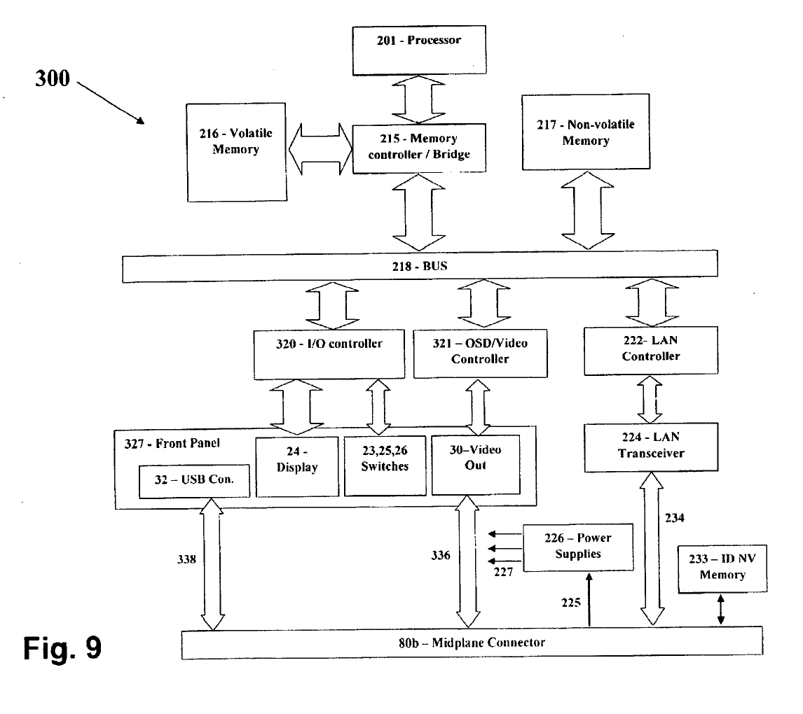

Reference is now made to FIG. 9 illustrating a block diagram of a management module 300 in accordance with a preferred embodiment of the present invention.

The structure of management module 300 may be similar to the thin-client blade module described in the previous FIG. 8 or it may be a simplified microcontroller design with reduced functionality. The module comprising of one or more of each of the following components:

Processor 201 process stored programs and data entered by user as needed, peripherals and network. Processor 201 is preferably chosen from available Reduced Instruction Set Computers (RISC) due to their lower power consumption and low heat generation. Alternatively, a Complex Instruction Set Computer (CISC), Security and encryption engine, Digital Signal Processor (DSP) or any other type or combinations of digital processor with sufficient processing power may be used. Processor 201 may include an on-die high speed cache memory or an external cache or combination of the two. Furthermore, processor 201 may be a simple low-cost microcontroller with integrated volatile and non-volatile memory.

A Memory controller/bridge 215 interface processor 201 with the volatile memory 216 and Bus 218. This function and others may be integrated with processor 201 or installed separately in different chips or chip-sets. Volatile memory 216 is used for storage of temporary data as needed by processor 201. Memory 216 may be RAM type, SDRAM, DDRAM or any other type of volatile memory.

Internal bus 218 connects the various parts of the Thin-client blade module and may be a single or multiple buses 16, 32 or 64 bit PCI or any other bus type. If multiple buses are implemented then bus bridges modules may be added to interface and drive the different buses.

Non-volatile memory 217, connected to bus 218, permanently stores data, programs and settings required for the Management module operation. Management programs and the various state machines required are loaded on this memory from connected removable media or from the centralized management system.

I/O controller 220 connected to bus 218 on one side and to the various controls and user interface functions of the module front panel. This includes, but not limited to, driving the panel display 24 and the switches 23, 25 and 26 shown in FIG. 3 herein above. Panel display 24 may be 7-segment, alphanumeric, dot matrix or fully graphical display if needed. The switches may include various function keys and switches to enable interaction with the user.

Optional On Screen Display (OSD)/Video controller module 321, is connected to bus 218 from one side and to video signals passed through the management module on the other side. It is used to enable the Management module to superimpose alphanumerical texts and symbols on the visible video image. The text presented may include identification and status of the Thin-client blade module selected or any other system status and configuration information. The video signal generated by this module is automatically synchronized to the optional On Screen Display (OSD)/Video controller module 321 may contain internal video memory, external video memory or it may share volatile memory 216 with processor 201 in Unified Memory Architecture (UMA) structure. Local Area Network controller or Media Access Controller (MAC) 222, connected to bus 218 is used for interfacing the Management module with the Network switch or hub 120 through LAN transceiver (physical layer module) 224.

Video connector 30 located at the module front panel 327 combines the KVM output connected by link 336 and Midplane connector 80b and the optionally OSD/Video generated in the management module by the OSD/Video processor 321. USB connectors 32 located on the front panel 327 are connected to the KVM module via link 338 and Midplane connector 80b. This port enables the user to connect a keyboard and mouse to the KVM port to manage the system.

Optional Local Area Network 224 transceiver (physical layer module) interface between a LAN controller (MAC) 222 and the LAN jack located at the front panel of thin client lade module 40. It is also optionally connected to Midplane connector 80b through link 224 to enable internal Network switch implementation. Transceiver 224 may contain a discrete magnetics or implement a direct connection without magnetics to the internal switch physical layer circuit.

LAN Transceiver 224 may be connected to the Local Area Network controller 222 by means of Media Independent Interface (MII) bus or by other interconnection buses. Local Area Network 224 transceiver may support 100 BASE-TX, 100 BASE-FX, 10 BASE-T and Giga LAN or other LAN protocols as required.

Power supplies 226 uses the power available on Midplane bus through Midplane connector 80b and link 225 to convert that power into the appropriate voltage/s output 227 required by the different Management module circuits. Power supplies module 226 may also include timing circuitry to provide power-up sequencing for other circuits. It also may contain reset signal/s generation to enable proper starting and power interruption detection.

Midplane connector 80b may also be connected to an optional Identification Non-volatile memory module 223. This memory module may be used to store the specific Management module model, serial number, MAC address, various module settings, and configuration.

Management module can operate in an override mode directly by pushbuttons 18 located at each thin-client blade module panel (shown in FIG. 2a). This enables the user to quickly monitor and control a specific module when necessary.

Optionally, management module 42 further comprises a memory device 233 installed in each management module 42 and accessible to the server to positively identify the type model and unique characteristics of that module.

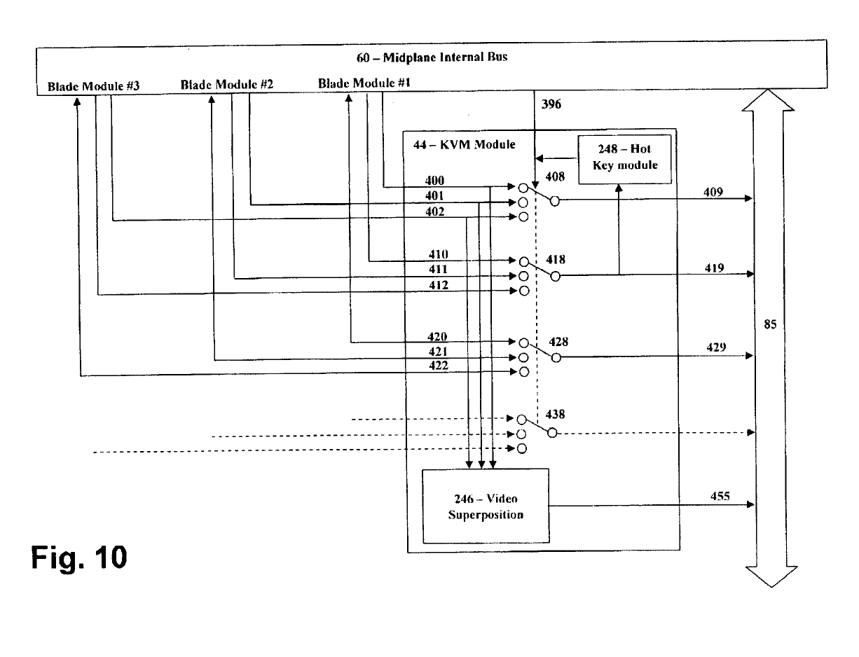

Reference is now made to FIG. 10 presenting KVM module 44 in greater details. For clarity, only minimal number of signals and ports are shown. Also, mechanical switches used in the schematic although various switching methods can be used including digital logic, analog switches, relays and so forth.

Signal 400 is thin-client blade module #1 video output signal routed through Midplane Internal Bus 60. Similar to that signal, 401 is a video signal thin-client blade module #2 and so on. Switch 408 serves as a selector switch to enable selection of just single video source based on selection command generated the Management module or by the KVM over IP module and passed through Midplane Internal Bus 60 and link 396. The single video output signal 409 provides connected to the single connected user display.

Similarly Switch 418 selects between the different USB ports 410, 411 and 412 of the different Thin-client blade modules. The port selected by the switch will be present at the single output 419. Additional switches may be added here to enable simultaneous switching from many sources and additional type of signals like audio and serial ports. When KVM over IP is implemented, KVM control 396 and all KVM outputs 409, 419, 429 are connected to the KVM over IP module.

Optional Hot Key module 240 can detect specific keyboard keys combination to toggle between the different Thin-client blade modules shown. This is done by connecting the USB port of the KVM 419, detecting the preprogrammed Hot Keys, and generating appropriate switching commands to KVM control signal 396.

Another optional module in the KVM is the Video Superposition processor 246. This module enables the video images generated by multiple thin-client modules to combine into a single display shown to the user. By connecting to different video sources 400, 401, 402 . . . the module captures video signals from all available sources. The module then rescales the selected video inputs and synchronizes them to fit into a large collage type picture available as single video output 455.

Thin-client blades 40 or 41 may have different hardware construction or configuration from each other. For example they may differ in memory capacity, operation speed, processor type, optional connectors, etc.

The modular system may operate with partially populated chassis; blades may be missing or replaced with blank cover. Blades may be turned on or off independently. In some embodiments of the present invention, blades may be removed or inserted while the other blades are operating (hot swapping).

Generally, each of the thin-client blades 40 or 41 may execute different software essentially independent from the other blades.

In order to create a simulation of an organization, a specific program is installed on the PC or thin-client of at least one “typical user” in the organization. That program monitors everything that the user is doing with the computer in details. Information about the user's use of his computer is stored with together with time stamps.

After data was collected over a period of time, one can parse that data to create random transactions with similar resources load (i.e. if the user typed an email with specific text and send it to a specific address, this action may be duplicated by replacing that text and e-mail addresses with random text and text address.

Integration over time and several users will create a working week “script” that statistically characterize a group of employees in the organization. For example, the representative work of a tellers in the bank. Several types of uses may thus be monitored and simulated creating an accurate representation of the workload and work balance of the organization.

For testing, each of the blades is simulating a user by “playing” one or more of these scripts to create an over all picture that statistically represents the overall organization activity profile over its business operation hours.

It should be noted that internally, each blade might faithfully represent a user using a thin-client station. However, for testing the ability of the servers, the communication links and the organization as whole, each blade representing a user performing a work session and thus the blade may simulate a thin-client station, a PC, or even non-human operated function such as server, an automatic machine or a system comprises of several computers or computer systems.

While the invention has been described with reference to certain exemplary embodiments, various modifications will be readily apparent to and may be readily accomplished by persons skilled in the art without departing from the spirit and scope of the above teachings.

It should be understood that features and/or steps described with respect to one embodiment may be used with other embodiments and that not all embodiments of the invention have all of the features and/or steps shown in a particular figure or described with respect to one of the embodiments. Variations of embodiments described will occur to persons of the art.

It is noted that some of the above described embodiments may describe the best mode contemplated by the inventors and therefore include structure, acts or details of structures and acts that may not be essential to the invention and which are described as examples. Structure and acts described herein are replaceable by equivalents which perform the same function, even if the structure or acts are different, as known in the art. Therefore, the scope of the invention is limited only by the elements and limitations as used in the claims. The terms “comprise”, “include” and their conjugates as used herein mean “include but are not necessarily limited to”.

1. A modular thin-client blade system, comprising:
at least one backplane having connectors, a common power bus and management bus;
a plurality of thin-client blade modules removeably connectable to said at least one backplane through mating connectors compatible with said connectors;
a modular chassis having multiple bays capable of accepting said plurality of thin-client blade module wherein each of said connectors is positioned in one of said multiple bays;
at least one network interface adapted to connect each of said plurality of thin-client blade modules to a network through a network switch.

2. The system according to claim 1, further comprises a KVM module capable of connecting a user keyboard, mouse and display to a selectable one of said plurality of thin-client blade modules.

3. The system according to claim 2, where said KVM module is adapted to chain with plurality of substantially similar systems to enable centralized management of more then one said chassis.

4. The system according to claim 2, where said KVM module is adapted to recognizing preprogrammed user's keyboard entries to trigger specific KVM actions.

5. The system according to claim 2, wherein said KVM module is adapted to combine multiple video images from multiple of said plurality of thin-client blade modules into a single displayed image.

6. The system according to claim 2, wherein the said KVM module is adapted to connect to remote or local sites using web-server to deliver video and to receive keyboard and mouse commands through a web browser.

7. The system according to claim 2, wherein the said KVM module is capable of overlaying alphanumeric data and system status on the visible video display.

8. The system according to claim 1, further comprises at least one power supply modules removeably connectable to said chassis so as to provide power to said plurality of thin-client blades modules.

9. The system according to claim 1, further comprises a management module to centrally monitor, configure and control each of said plurality of thin-client blade modules.

10. The system according to claim 1, wherein al least one of said plurality of thin-client blade modules is built with RISC architecture.

11. The system according to claim 1, wherein said network switch is manageable to allow flexible network configuration and connection to each of said plurality of thin-client blades modules in the system.

12. The system according to claim 1, wherein said network switch is adapted to restrict the bandwidth and packet flow characteristics to enable different network implementations and simulations.

13. The system according to claim 1, wherein one or more of said plurality of thin-client blade modules is running a local software that simulates the load of a specific or typical user.

14. The system according to claim 1, further comprises a cooling fan module coupled to said chassis to cool the system.

15. The system according to claim 1, further comprising a non-volatile memory device installed in each one of said plurality of thin-client blade module and accessible to a management module through a bus to positively identify the type model and unique characteristics of that module.

16. A thin-client blade chassis configured for accepting a plurality of insertable thin client blade modules, comprising:
a modular chassis having multiple bays capable of accepting the insertable thin-client blade module;
at least one backplane having connectors for each of said multiple bays, a common power bus, and management bus interconnecting said multiple bays;
a KVM module adapted to connect a user keyboard, mouse and display to a selectable one of the thin-client blade modules;
at least one power supply module adapted to provide power to said the insertable thin-client blade modules.

17. An insertable thin-client blade module device adapted to removably connect to a backplane connector so as to establish an interface for receiving power from the backplane connector and exchanging information through the backplane connector, the device comprising:
a mating connector adapted to connect to the backplane connector;
a LAN transceiver connected to said mating connector, to a LAN connector and to a LAN controller;
a processor processing the information;
a volatile memory for storing information and program instructions used by said processor;
a non-volatile memory for storing program instructions used by said processor; and
a bus adapted to connect said LAN controller, said non-volatile memory, said volatile memory and said processor.

18. The device according to claim 17, wherein the device further comprises at least one indicator indicating characteristics of the device.

19. An insertable management module adapted to releasably connect to backplane connector so as to establish an interface for receiving power from the backplane connector and exchanging information through the backplane connector, the module comprising:
a mating connector adapted to establish an interface with the backplane connector;
a LAN transceiver connected to said mating connector and to a LAN controller;
a processor adapted to process the information;
a volatile memory for storing information and program instructions used by said processor;
a non-volatile memory for storing program instructions used by said processor;
an I/O controller adapted to exchange information with user input/output device;
a video controller adapted to generate video signals; and
a bus connecting said I/O controller, said video controller, said LAN controller, said non-volatile memory, said volatile memory and said processor.

20. A method for constructing large scale, centrally manageable multi thin-client system comprising the step of:
providing plurality of modular chassis, wherein each chassis is adapted to accept at least one of a plurality of insertable thin client blade modules, said modular chassis comprises:
i. multiple bays adapted to accept said at least one of a plurality of insertable thin-client blade module;
ii. at least one backplane having connectors for each of said multiple bays, a common power bus and management bus interconnecting said multiple bays; and
iii. a KVM module adapted to connect a user keyboard, mouse and display to a selectable one of said insertable thin-client blade modules; and
chaining said KVM modules of at least two of said plurality of modlar chassis.

21. A method for simulating a multi thin-client system comprising:
providing a plurality of modular chassis, each modular chassis is adapted to accept a plurality of insertable thin client blades;
inserting said plurality of insertable thin-client blades and a single management module in each of said plurality of modular chassis;
connecting each of said plurality of thin-client blades to a network switch; and
connecting said network switch to a server.

22. A modular chassis having multiple bays adapted to accept a plurality of thin-client blade modules, the modular chassis comprising:
at least one backplane having connectors, a common power bus and management bus; and
a KVM module adapted to connect a user keyboard, mouse and display to a selectable one of the plurality of thin-client blade modules.

23. The modular chassis according to claim 22, wherein said KVM module is adapted to chain with a plurality of substantially similar systems to enable centralized management of more than one modular chassis.

24. The modular chassis according to claim 22, wherein said KVM module is adapted to recognize preprogrammed user's keyboard entries to trigger specific KVM actions.

25. The modular chassis according to claim 22, wherein said KVM module is adapted to combine multiple video images from multiple of the thin-client blade modules into a single displayed image.

26. The modular chassis according to claim 22, wherein said KVM module is adapted to connect to remote or local sites using web-server to deliver video and to receive keyboard and mouse commands through a web browser.

27. The modular chassis according to claim 22, further comprises at least one power supply modules removeably connectable to the modular chassis so as to provide power to the plurality of thin-client blades modules.

28. The modular chassis according to claim 22, wherein the modular chassis is adapted to accept a management module to centrally monitor, configure and control each of the plurality of thin-client blade modules.
